(19) United States
(12) Patent Application Publication
(10) Pub. No.: US 2008/0008940 A1
(43) Pub. Date: Jan. 10, 2008

(54) Glass mask used for patterning and manufacturing method and apparatus therefor

(75) Inventors: Kazuhide Uemura, Higashimorokata (JP); Yasuhiko Nakayama, Miyazaki (JP)

Correspondence Address: STAAS & HALSEY LLP, SUITE 700, 1201 NEW YORK AVENUE, N.W., WASHINGTON, DC, 20005, US

(73) Assignee: Fujitsu Hitachi Plasma Display Limited, Miyazaki (JP)

(21) Appl. No.: 11/641,711

(22) Filed: Dec. 20, 2006

(30) Foreign Application Priority Data
Jul. 6, 2006 (JP) 2006-187032

(51) Int. Cl. G03F 1/00; B28B 11/00

(52) U.S. Cl. 430/5; 425/506

(57) ABSTRACT

A glass mask used for patterning includes a plurality of glass plates superposed on one after another and a pattern formation layer formed on at least one of the glass plates. This structure makes it possible to suppress degradation in patterning precision due to warping of a photomask.

### CROSS-REFERENCE TO RELATED APPLICATION

This application is related to Japanese patent application No. 2006-187032 filed on Jul. 6, 2006 whose priority is claimed under 35 USC § 119, the disclosure of which is incorporated by reference in its entirety.

### BACKGROUND OF THE INVENTION

1. Field of the Invention

The present invention relates to a glass mask used for patterning and manufacturing method and apparatus for such a mask, and more particularly relates to a transmission-type exposing technique using a photomask, which is applied to a patterning process for patterning electrodes and the like of a semiconductor element, a liquid crystal display or a plasma display.

2. Description of the Related Art

In a patterning process used for manufacturing processes of a semiconductor element, a liquid crystal display, a plasma display and the like, for example, the method is mainly used in which a pattern of electrodes and the like is formed by a glass mask having a pattern defined on quartz glass or soda lime glass using a chromium or chromium oxide thin film. However, as the exposing area of a subject to be patterned becomes larger, the area of the glass mask has to become larger, and the resulting problem is that the patterning precision deteriorates due to warping caused by its own weight of the glass mask. By making the glass mask thicker in response to the larger size of the glass mask area so as to increase its rigidity, the warping can be alleviated. However, it becomes difficult to produce glass with high purity since possibility of inclusion of bubbles and impurities in the glass mask is higher. As a result, pattern defects occur in the product.

With respect to the method for solving such problems, a method in which an external force is applied to the glass mask by using a cylinder or the like, or an atmospheric pressure difference is utilized in order to forcefully reduce the warping, and a method in which the shape of the patterning subject is forcefully changed in accordance with the amount of warping of the glass mask so as to prevent degradation in the patterning precision due to the warping, have been proposed (for example, see Japanese Patent Application Laid-Open Nos. 2003-167355 and 2003-131388).

In the above-mentioned conventional methods, however, a warping-amount measuring means with high precision and a means for feeding back the corresponding information so as to change the shapes of a glass mask and a patterning subject with high precision have to be installed, with the result that the exposing apparatus totally becomes expensive.

Moreover, additional processes in which the amounts of warping of the glass mask and the patterning subject are measured and the glass mask and the patterning subject are deformed based upon the measured amounts are required, with the result that the processing tact of the product becomes longer to cause degradation in the productivity.

Furthermore, there is a risk that the shape of a glass mask and the material and the shape of a patterning subject, when an external pressure is forcefully applied, cause the glass mask and the patterning subject to be damaged.

### SUMMARY OF THE INVENTION

The present invention provides a glass mask used for patterning comprising: a plurality of glass plates superposed on one after another; and a pattern formation layer formed on at least one of the glass plates.

In another aspect, the present invention provides a method of manufacturing a glass mask used for patterning comprising the steps of: immersing a plurality of glass plates in a processing vessel housing a curing-type liquid bonding agent, the glass plates superposed on one after another, at least one of the glass plates having a pattern formation layer thereon; injecting the bonding agent between every one pair of adjacent glass plates; and taking the glass plates out of the processing vessel to cure the bonding agent between the glass plates.

In another aspect, the present invention provides a manufacturing apparatus for a glass mask used for patterning, comprising: a processing vessel housing a curing-type liquid bonding agent; a transporting unit which immerses first and second glass plates in the processing vessel with the glass plates superposed on one after another, and takes the first and second glass plates out of the processing vessel; and an injecting unit which injects and fill in the curing-type liquid bonding agent between the first and second glass plates when the first and second glass plates are immersed in the processing vessel.

In accordance with the present invention, by using a glass mask having a structure in which a plurality of glass plates are superposed on one after another, the same effects as those obtained by making the glass mask thicker to increase the rigidity can be obtained so that the warping of the mask can be reduced. Moreover, since it is not necessary to make the glass plate itself thicker, glass with high purity, which has been easily produced at low costs, can be used as the material for a photomask. Furthermore, since the glass mask in itself is allowed to have sufficient rigidity and reduced warping, it becomes possible to eliminate the necessity of preparing a means used for measuring the amount of warping with high precision as well as a means used for feeding back the corresponding information so as to change the shapes of a glass mask and a subject to be patterned with high precision, and consequently to reduce total costs of the exposing apparatus, improve the productivity through shortened processing tacks of the products and carry out a patterning process with high precision.

### BRIEF DESCRIPTION OF THE DRAWINGS

FIG. 1 is an explanatory drawing that shows a structure of a glass mask used for patterning in accordance with the present invention;

FIG. 2 is an explanatory drawing that shows a structure of a manufacturing apparatus in accordance with the present invention;

FIG. 3 is an explanatory drawing that shows an exposing device in which the glass mask used for patterning in accordance with the present invention is used; and

FIG. 4 is a block diagram that shows a control unit of the exposing device shown in FIG. 3.

### DETAILED DESCRIPTION OF THE PREFERRED EXAMPLES

A glass mask of the present invention comprises: a plurality of glass plates superposed on one after another; and a pattern formation layer formed on at least one of the glass plates.

The glass mask may further comprise: a light-transmitting member that is inserted between the glass plates.

The light-transmitting member may be made from a material having an adhesive property.

Each glass plate may be made from one of soda lime glass, high distortion point glass, quartz glass, synthetic quartz glass, borosilicate glass, aluminosilicate glass, lead glass and borate glass.

The pattern formation layer may be made from a material containing at least one of a silver salt emulsion, chromium and chromium oxide.

A method of manufacturing a glass mask of the present invention patterning comprises the steps of: immersing a plurality of glass plates in a processing vessel housing a curing-type liquid bonding agent, the glass plates superposed on one after another, at least one of the glass plates having a pattern formation layer thereon; injecting the bonding agent between every one pair of adjacent glass plates; and taking the glass plates out of the processing vessel to cure the bonding agent between the glass plates.

The curing-type bonding agent may be one of ultraviolet curing type epoxy resin, ultraviolet curing type acrylic resin, thermosetting type acrylic resin and thermosetting type epoxy resin.

A manufacturing apparatus for a glass mask of the invention, comprises: a processing vessel housing a curing-type liquid bonding agent; a transporting unit which immerses first and second glass plates in the processing vessel with the glass plates superposed on one after another, and takes the first and second glass plates out of the processing vessel; and an injecting unit which injects and fill in the curing-type liquid bonding agent between the first and second glass plates when the first and second glass plates are immersed in the processing vessel.

One of the first and second glass plates preliminarily may include a pattern formation layer thereon.

The following description will discuss the present invention by using embodiments shown in the drawings.

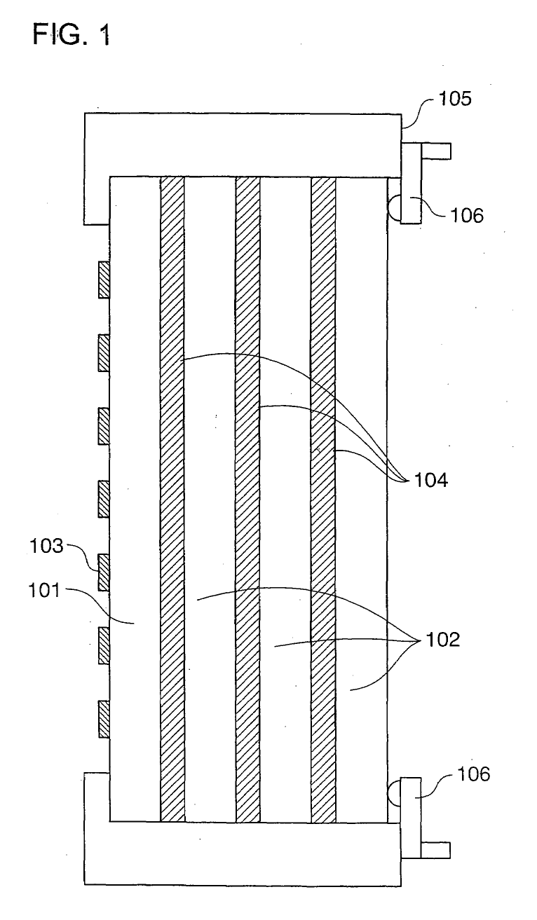

FIG. 1 is a schematic drawing that shows a structure of a glass mask used for patterning in accordance with the present invention. The glass mask used for patterning, shown in FIG. 1, is a glass mask having a four-layered structure in which four glass plates are laminated.

FIG. 1 shows a patterning glass plate 101 on which an exposing pattern formation layer 103 is formed. With respect to the material for this glass plate 101, a glass material, such as soda lime glass, glass of SiO₂—Al₂O₃—R₂O—R′O (R₂O: alkaline oxide, R′O: alkali earth metal oxide) type, referred to as high distortion point glass, which is formed by allowing soda lime glass to have a heat resistance to suppress expansion and shrinkage due to heat, or quartz glass as well as synthesized quartz glass can be mentioned.

With respect to the manufacturing method for soda lime glass, a float method, a fusion method and the like are generally used, and a manufacturing process for soda lime glass used for photomasks through the above-mentioned float method or fusion method is easier and inexpensive in comparison with that for quartz glass. However, when the glass plate thickness of the soda lime glass used for photomasks is made thicker in an attempt to reduce distortion, a problem arises in which bubbles, impurities and the like are easily included in those products manufactured through the float method or fusion method. Therefore, in the case when soda lime glass is used, the thickness of the glass plate 101 with a pattern is set to such a thickness as not to allow bubbles, impurities or the like to intrude therein. Here, the number of the glass plates 101, each having a pattern formation layer 103, may be set to one or more.

FIG. 1 shows an elementary glass plate 102, and with respect to the material, soda lime glass and high distortion point glass, as well as quartz glass and synthesized quartz glass, are listed in the same manner as in the glass plate 101, and in this case, the same material as that of the glass plate 101 is used. The thickness of the elementary glass plate 102 is set to an optional thickness such that no bubbles and impurities are allowed to intrude therein, in the same manner as in the glass plate 101.

Moreover, with respect to the material for the pattern formation layer 103, one or more kinds of materials selected from a silver salt emulsion, chromium and chromium oxide may be used. With respect to the formation method of the pattern formation layer 103, a conventionally known method, such as a laser direct plotting method and an electron beam direct plotting method, may be used.

FIG. 1 shows light-transmitting members 104 each having a refractive index that is the same as that of the glass plates 101 and 102. Although the material of the members 104 is desirably determined, the material preferably has the following properties.
It has a good adhesive property to the glass plates 101 and 102.
It is in a liquid state when introduced in between the glass plates.
It is capable of removing bubbles and impurities preliminarily mingled between the glass plates.
It can be cured by using an optional method to increase the adhesive property.

With respect to this material, for example, an ultraviolet curing type epoxy resin F-UVE 63 made by New Port Co., Ltd. in the U.S. may be used. With respect to the method used for removing bubbles and impurities, a method in which a light-transmitting liquid member is circulated so that the bubbles and impurities are discharged together with the light-transmitting liquid member that is being circulated, and a conventionally-known defoaming method using vibration and ultrasonic waves can be mentioned.

FIG. 1 shows a support member 105 used for supporting the glass plates 101 and 102. A material having small expansion and shrinkage against heat and high rigidity is used for the supporting member 105. A plunger 106 presses the glass plates 101 and 102 onto the supporting member 105 to secure them. Here, with respect to the shape of the support member 105 and the plunger 106, in addition to the shape as shown in FIG. 1 that only supports the upper and lower portions, a structure that surrounds the peripheral portion of the glass plates may be used. Any structure may be used as long as it can exert the effects of securing and supporting the glass plates 101 and 102.

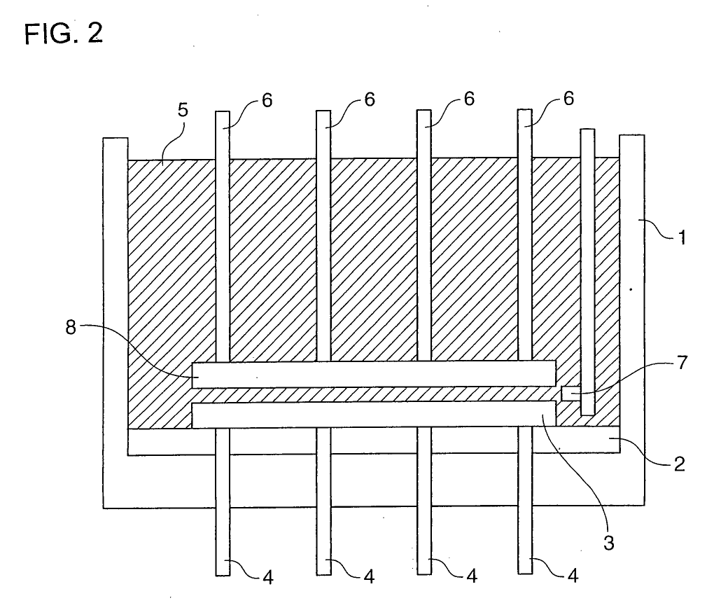

FIG. 2 is an explanatory drawing that shows a manufacturing apparatus for a glass mask for patterning in accordance with the present invention. As shown in this Figure, a processing vessel 1 that houses liquid 5 is installed, and a mount base 2 is placed on the inner bottom face. Here, the mount base 2 can mount a glass plate 3 thereon in a manner so as not to cause warping.

A plurality of lift shafts 4, which penetrate the mount base 2 and the bottom of the processing vessel 1, are adapted to lift the glass plate 3 up and support it in a manner so as not to cause warping. In contrast, a plurality of glass supporting shafts 6, which are inserted from the upper opening of the processing vessel 1, are provided with a suction pad on the tips thereof so that they support the glass plate 8 in a manner so as not to cause warping and allow it to descend into the processing vessel 1. Thereby, the glass plate 8 is opposed to the glass plate 3 with a predetermined gap in between. Moreover, an injection nozzle 7 is adapted to be inserted into the processing vessel 1 so that it injects the liquid 5 between the opposing glass plates 3 and 6.

The following description will discuss a method of manufacturing a glass mask for patterning by using such a manufacturing apparatus.

First, a ultraviolet curing type liquid epoxy resin, which is cured by ultraviolet rays having a wavelength of 200 to 380 nm, is poured into a processing vessel 1 as the liquid 5 to fill it up. Here, this manufacturing environment is kept free from ultraviolet rays having a wavelength of 200 to 380 nm.

Next, the elementary glass plate 102 (FIG. 1) is put into the processing vessel 1 as the glass plate 3, and the glass plate 101 (FIG. 1) is also put into the processing vessel 1 as the glass plate 8, as shown in FIG. 2, so that these are opposed to each other with a predetermined interval in between. Next, the above-mentioned epoxy resin 5 is injected in between the glass plates 3 and 8 from the nozzle 7 so that the gap is filled with the epoxy resin while bubbles and foreign matters are removed from a gap between the glass plate 3 and 8.

Next, the glass plates 3 and 8 (the element glass 102 and the glass plate 101) filled with the epoxy resin are supported and lifted by the glass supporting shafts 6 and lift shafts 4, and taken out of the processing vessel 1.

A leak preventive seal is attached to the peripheral edge of the glass plates 3 and 8 thus taken out.

Next, the epoxy resin adhered to the surfaces of the glass plates 3 and 8 is removed.

Next, the glass plate 3 or 8 is irradiated with ultraviolet rays having wavelengths from 200 to 380 nm so that the epoxy resin between the glass plates 3 and 8 is cured to bond the glass plates 3 and 8 to each other.

Thus, a two-layered glass plate (laminated structure of the elementary glass and the patterning glass) is formed.

Next, this two-layered glass plate is used as the glass plate 8 (FIG. 2) and the elementary glass plate 102 is used as the glass plate 3 (FIG. 2), and these are put into the processing vessel 1. By repeating the above-mentioned processes, a three-layered glass plate in which the elementary glass plate 102 is laminated on the two-layered glass plate is formed.

By repeating these processes, a glass mask for patterning having a four-layered structure as shown in FIG. 1 (a laminated structure including one patterning glass plate and three elementary glass plates) is completed.

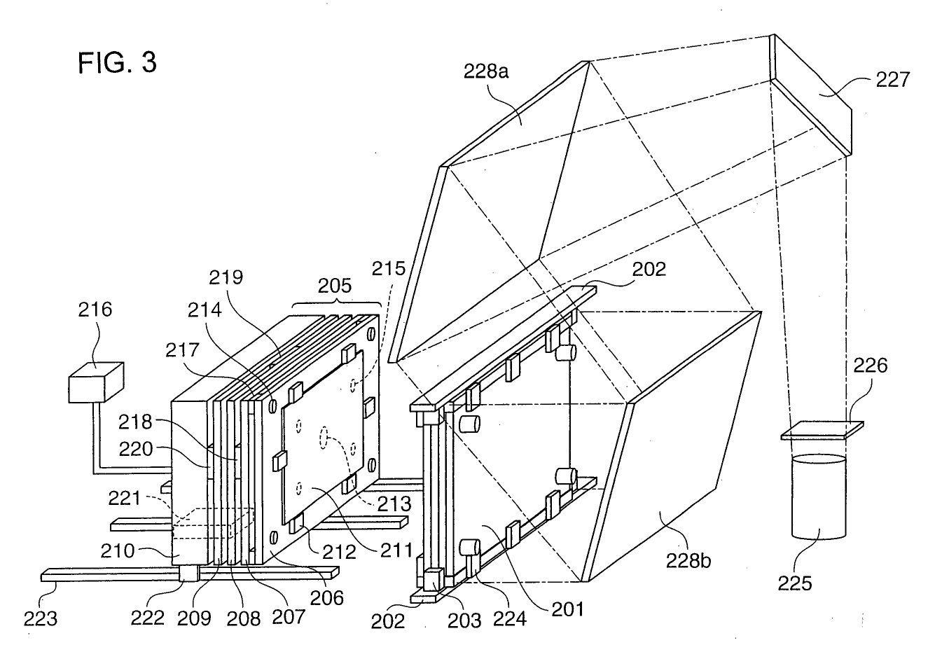

FIG. 3 is an explanatory drawing that shows an exposing device in which the glass mask used for patterning in accordance with the present invention is used.

In FIG. 3, reference numeral 201 represents the glass mask for patterning shown in FIG. 1. Guides 202 are placed on the upper and lower portions of the glass mask 201, with the glass mask 201 used for patterning being secured by a block 203, so that the glass mask 201 used for patterning can be exchanged easily.

In FIG. 3, reference numeral 205 represents an exposing stage that supports a substrate 211 used for a plasma display panel (hereinafter, referred to as PDP). The exposing stage 205 is constituted by a suction regulating table 206, a θ-axis table 207, an X-axis table 208, a Y-axis table 209 and a table supporting base 210.

The suction regulating table 206 is constituted by a substrate supporting means 212 that regulates and supports the substrate 211 used for a PDP from up and down positions as well as from right and left positions, a photo-sensor 213 used for detecting the presence or absence of a substrate, a light-quantity measuring means 214 used for measuring the quantity of light of UV light irradiation, and a suction hole 215 that brings a face on which the substrate 211 used for a PDP and the suction regulating table 206 are made in contact with each other into a vacuum state so that these members are suction-secured to each other through the atmospheric pressure. Here, discharge of a gas from the suction hole 215 is carried out by a gas discharging means 216. The gas discharging means 216 is preferably prepared as a rotary pump.

Moreover, a tilt changing means 217 for the suction regulating table 206 is attached between the suction regulating table 206 and the θ-axis table 207 so that the tilt change of the glass mask 201 used for patterning in the Z-axis direction is set to an optional amount. The tilt changing means 217 is preferably prepared as a servomotor.

A θ-axis table shifting means 218, an X-axis table shifting means 219 and a Y-axis table shifting means 220, which are table shifting means used for shifting the respective tables, are attached to the θ-axis table 207, the X-axis table 208 and the Y-axis table 209 so that these tables can be moved in optional directions. These table shifting means 218, 219 and 220 are preferably prepared as servomotors.

The suction regulating table 206, the θ-axis table 207, the X-axis table 208 and the Y-axis table 209 are supported by a table supporting base 210. A base shifting means 221 used for shifting the table supporting base 210 in the Z-axis direction is attached to the table supporting base 210. Here, the table supporting base 210 is supported by stage supporting means 222 and 223.

In this case, the means used for changing the positional relationship between the glass mask 201 used for patterning and the exposing stage 205 is prepared as a structure that changes the exposing stage 205 side; however, this may be prepared as a structure that changes the position of the glass mask 201 used for patterning.

In FIG. 3, reference numeral 224 represents a measuring means used for measuring the positional relationship between the mask 201 used for patterning and the substrate 211 for a PDP. The measuring means 224 is constituted by an alignment camera that reads a mark displayed on the PDP substrate 211 or the exposing stage 205 and a mark displayed on the glass mask 201 used for patterning by using a camera so that the positional relationships in the X- and Y-axis directions are measured, and a gap sensor that applies a laser light beam and reads a light path difference between reflected light from the interface between the glass mask 201 used for patterning and the gas and reflected light from the surface of the PDP substrate so that the positional relationship in the Z-axis direction is measured.

An exposing light source is constituted by a UV lamp 225, a shielding shutter 226 that shields UV light, a reflective mirror 227 that reflects UV light, and parallel light mirrors 228a and 228b that form UV light into parallel light and reflect the light. The UV light of the UV lamp 225 is prepared as light having wavelengths that are allowed to transmit the glass mask 201 used for patterning most easily and most effectively expose a resin having a photosensitive modifying property that has been applied onto the surface of the PDP substrate 211. The light shielding shutter 226 has a structure that is provided with a driving mechanism so as to be opened and closed on demand. Moreover, the reflective mirror 227 and the parallel light mirrors 228a and 228b are designed so as to have the highest reflection factor to the wavelengths of the UV lamp 225.

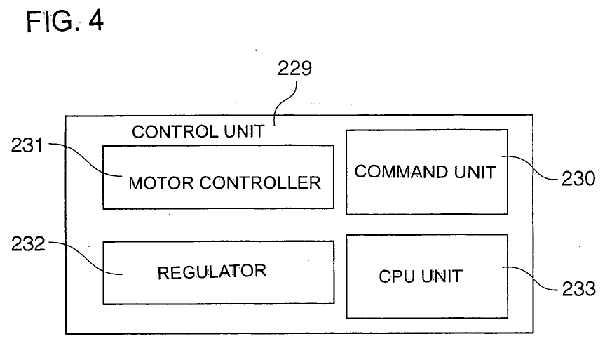

In FIG. 4, reference numeral 229 represents a control unit that controls operations of the gas discharging means 216, the tilt-changing means 217, the photo-sensor 213, the light quantity measuring means 214, the table shifting means 218, 219 and 220, the base shifting means 221, the positional relationship measuring means 224 and the light-shielding shutter 226. The control unit 229 is provided with a command unit 230 such as a sequencer, a motor controller 231, a regulator 232 used for pressure control, and a CPU unit 233 that executes computing processes on image data and laser reflection light data obtained from the positional relationship measuring means 214.

The following description will discuss exposing operations in the exposing device having the above-mentioned structure. When the PDP substrate 211 is set onto the exposing stage 205, the photo-sensor 213 confirms the existence of the PDP substrate 211 so that it is secured by the substrate supporting means 212 and the suction hole 215. Successively, the positional relationship between the glass mask 201 used for patterning and the PDP substrate 211 or the suction regulating table 206 is measured by the positional relationship measuring means 224.

The results of measurements by the positional relationship measuring means 224 are computed by the CPU unit 233, and the amount of shift and the amount of change are sent to the motor controller 231. Next, the motor controller 231 outputs operation instructions to the tilt changing means 217, the table shifting means 218, 219 and 220, and the base shifting means 221 so that alignment operations are carried out between the PDP substrate 211 and the glass mask 201 used for patterning.

Next, the light-shielding shutter 226 is opened so that UV light is applied to the PDP substrate 211 through the glass mask 201 used for patterning. The quantity of light is measured by the light-quantity measuring means 214 so that, upon irradiation of the UV light with a predetermined quantity of light, the light-shielding shutter 226 is closed, thereby completing the exposing operations.

The above-mentioned description has explained a patterning process in a PDP manufacturing process; however, the present invention may be applied to patterning processes in other manufacturing processes.

What is claimed is:

1. A glass mask used for patterning comprising:
a plurality of glass plates superposed on one after another; and
a pattern formation layer formed on at least one of the glass plates.

2. The glass mask used for patterning according to claim 1, further comprising:
a light-transmitting member that is inserted between the glass plates.

3. The glass mask used for patterning according to claim 2, wherein the light-transmitting member is made from a material having an adhesive property.

4. The glass mask used for patterning according to claim 1, wherein each glass plate is made from one of soda lime glass, high distortion point glass, quartz glass, synthetic quartz glass, borosilicate glass, aluminosilicate glass, lead glass and borate glass.

5. The glass mask used for patterning according to claim 1, wherein the pattern formation layer is made from a material containing at least one of a silver salt emulsion, chromium and chromium oxide.

6. A method of manufacturing a glass mask used for patterning comprising the steps of:
immersing a plurality of glass plates in a processing vessel housing a curing-type liquid bonding agent, the glass plates superposed on one after another, at least one of the glass plates having a pattern formation layer thereon;
injecting the bonding agent between every one pair of adjacent glass plates; and
taking the glass plates out of the processing vessel to cure the bonding agent between the glass plates.

7. The method of manufacturing a glass mask used for patterning according to claim 6, wherein the curing-type bonding agent is one of ultraviolet curing type epoxy resin, ultraviolet curing type acrylic resin, thermosetting type acrylic resin and thermosetting type epoxy resin.

8. A manufacturing apparatus for a glass mask used for patterning, comprising:
a processing vessel housing a curing-type liquid bonding agent;
a transporting unit which immerses first and second glass plates in the processing vessel with the glass plates superposed on one after another, and takes the first and second glass plates out of the processing vessel; and
an injecting unit which injects and fill in the curing-type liquid bonding agent between the first and second glass plates when the first and second glass plates are immersed in the processing vessel.

9. The manufacturing apparatus for a glass mask used for patterning according to claim 8, wherein one of the first and second glass plates preliminarily includes a pattern formation layer thereon.
